(19) United States
(12) Patent Application Publication
(10) Pub. No.: US 2024/0224544 A1
(43) Pub. Date: Jul. 4, 2024

(54) PROCESSOR CHIP AND SEMICONDUCTOR PACKAGE INCLUDING THE SAME

(71) Applicant: SAMSUNG ELECTRONICS CO., LTD., Suwon-si (KR)

(72) Inventors: KIHONG JEONG, Suwon-si (KR); Sangsub SONG, Suwon-si (KR); Heewoo AN, Suwon-si (KR)

(21) Appl. No.: 18/512,199

(22) Filed: Nov. 17, 2023

(30) Foreign Application Priority Data
Dec. 29, 2022 (KR) 10-2022-0189735

(51) Int. Cl. H10B 80/00; H01L 25/065; H01L 25/18

(52) U.S. Cl. CPC H10B 80/00; H01L 25/0652; H01L 25/0657; H01L 25/18; H01L 2225/06506; H01L 2225/0651; H01L 2225/06562; H01L 2225/06575; H01L 2225/06586

(57) ABSTRACT

A processor chip for a semiconductor package includes a substrate having a first surface and a second surface opposite to the first surface and mounted on a package substrate, and a plurality of chip pads disposed on the first surface of the substrate and electrically connected to the package substrate, wherein the first surface is divided into a first area and a second area, the first area includes four sides of the first surface and the second area includes a center of the first surface, and the plurality of chip pads are located on the first area and are arranged on at least a portion of a side of the first surface in a line along the side.

### CROSS-REFERENCE TO RELATED APPLICATION

This application is based on and claims priority under 35 U.S.C. § 119 to Korean Patent Application No. 10-2022-0189735, filed on Dec. 29, 2022, in the Korean Intellectual Property Office, the disclosure of which is incorporated by reference herein in its entirety.

### BACKGROUND

### 1. Field

Embodiments relate to a processor chip and a semiconductor package including the same.

### 2. Description of the Related Art

In a multi-chip package in which a plurality of semiconductor chips are embedded, the number of semiconductor chips and the number of input/output (I/O) channels may increase for high capacity and high performance. In such multi-chip packages, the number of vertically stacked chips may be reduced by arranging the semiconductor chips in parallel with each other.

### SUMMARY

According to as an aspect of embodiments, there is provided a processor chip for a semiconductor package, the processor chip including: a substrate having a first surface and a second surface opposite to the first surface and mounted on a package substrate; and a plurality of chip pads disposed on the first surface of the substrate and electrically connected to the package substrate, wherein the first surface is divided into a first area and a second area, the first area includes four sides of the first surface and the second area includes a center of the first surface, and the plurality of chip pads are located in the first area and are arranged on at least a portion of a side of the first surface in a line along the side of the first surface.

According to an aspect of embodiments, there is provided a semiconductor package including: a package substrate including a plurality of substrate pads; a processor chip mounted on the package substrate and including a plurality of chip pads on an upper surface of the processor chip; a first stacked structure located on the package substrate and including a plurality of offset-stacked first memory chips; and a second stacked structure located on the package substrate and including a plurality of offset-stacked second memory chips, wherein the processor chip is divided into a first area and a second area, the first area includes four sides of an upper surface of the processor chip, the first area surrounds the second area, and the plurality of chip pads are located in the first area and are arranged on each side of the upper surface in a line in a direction parallel to the side of the upper surface.

According to an aspect of embodiments, there is provided a semiconductor package including: a package substrate including a plurality of first substrate pads and a plurality of second substrate pads; a processor chip mounted on the package substrate and including a plurality of first chip pads and a plurality of second chip pads on an upper surface of the processor chip; a first stacked structure located on the package substrate and including a plurality of offset-stacked first memory chips; and a second stacked structure located above the package substrate and including a plurality of offset-stacked second memory chips, wherein the processor chip is divided into a first area and a second area, the first area includes four sides of an upper surface of the processor chip and surrounds the second area, the plurality of first chip pads and the plurality of second chip pads are located in the first area and are arranged on each side of the upper surface in a line in a direction parallel to the side of the upper surface, the processor chip and the first stacked structure are wire-bonded to each other through the plurality of first substrate pads, and the processor chip and the second stacked structure are wire-bonded to each other through the plurality of second substrate pads.

### BRIEF DESCRIPTION OF THE DRAWINGS

Features will become apparent to those of skill in the art by describing in detail exemplary embodiments with reference to the attached drawings, in which:

FIG. 1 is a perspective view schematically illustrating a processor chip according to an embodiment;

FIG. 2 is a plan view schematically illustrating a processor chip according to an embodiment;

FIG. 3 is a cross-sectional view schematically illustrating a semiconductor package according to an embodiment;

FIG. 4 is a cross-sectional view schematically illustrating a semiconductor package according to an embodiment;

FIG. 5 is a cross-sectional view schematically illustrating a semiconductor package according to an embodiment;

FIG. 6 is a cross-sectional view schematically illustrating a semiconductor package according to an embodiment;

FIG. 7 is a cross-sectional view schematically illustrating a semiconductor package according to an embodiment;

FIG. 8 is a cross-sectional view schematically illustrating a semiconductor package according to an embodiment;

FIG. 9 is a cross-sectional view schematically illustrating a semiconductor package according to an embodiment; and

FIG. 10 is a cross-sectional view schematically illustrating a semiconductor package according to an embodiment;

### DETAILED DESCRIPTION

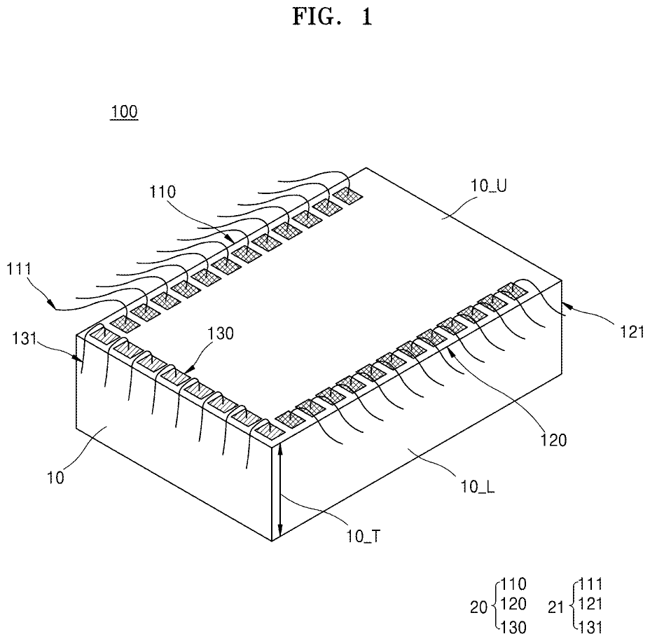

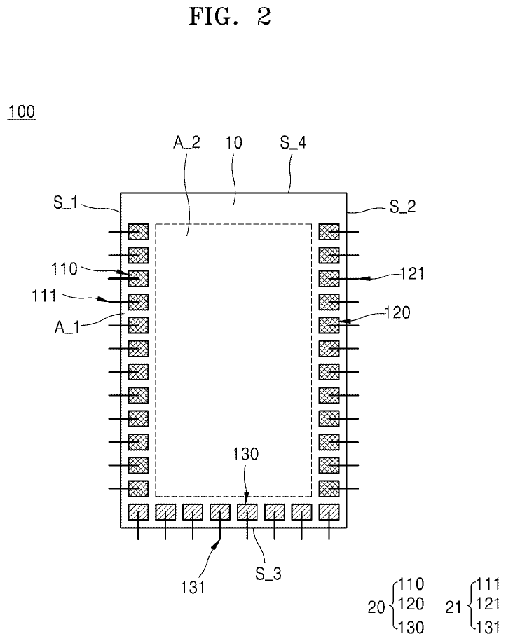

FIG. 1 is a perspective view schematically illustrating a processor chip 100 according to an embodiment. FIG. 2 is a plan view schematically illustrating the processor chip 100 according to an embodiment.

Referring to FIGS. 1 and 2, the processor chip 100 may include a substrate 10 and a plurality of chip pads 20.

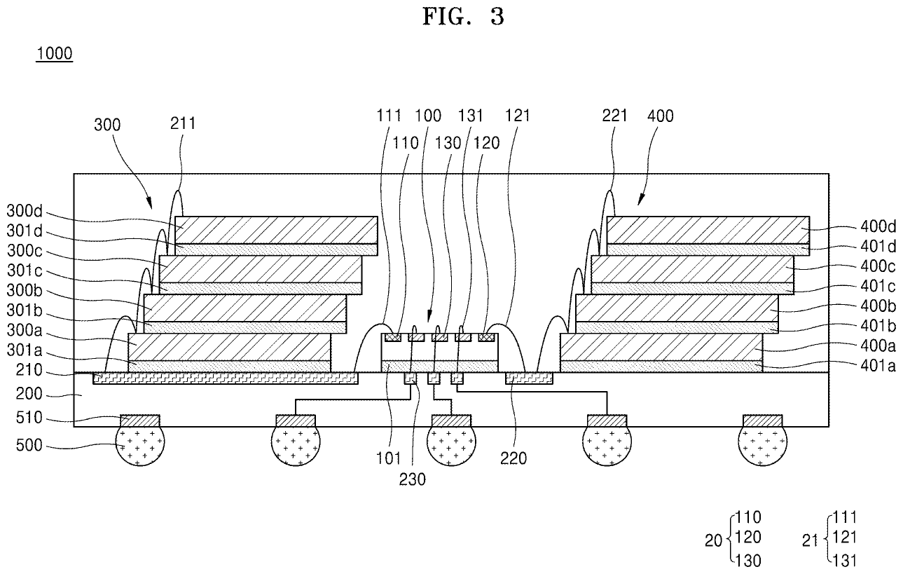

In some embodiments, the processor chip 100 may be attached to a package substrate of a semiconductor package and electrically connected to a stacked structure mounted on the semiconductor package. The processor chip 100 may be electrically connected to the package substrate and the stacked structure by using a wire bonding method. The package substrate and the stacked structure are described in detail with reference to FIG. 3.

As illustrated in FIG. 1, the substrate 10 of the processor chip 100 may include a first surface 10_U and a second surface 10_L opposite to the first surface 10_U, e.g., the first and second surfaces 10_U and 10_L may be parallel to each other. In some embodiments, the first surface 10_U of the substrate 10 may be an active surface, and the second surface 10_L of the substrate 10 may be an inactive surface. In some embodiments, a thickness 10_T of the substrate 10, e.g., a distance between the first and second surfaces 10_U and 10_L, may be between about 40 μm and about 60 μm.

As illustrated in FIG. 2, the first surface 10_U of the substrate 10 may be divided into a first area A_1 and a second area A_2. The first area A_1 may include four sides S_1, S_2, S_3, and S_4 of the first surface 10_U, and the second area A_2 may be surrounded by the first area A_1. That is, the first area A_1 may be an area including the edge (e.g., periphery) of the first surface 10_U, and the second area A_2 may be an area including the center of the first surface 10_U. For example, as illustrated in FIG. 2, the second area A_2 may be an area at the center of the first surface 10_U, and the first area A_1 may include four linear portions along the four sides of the first surface 10_U, respectively, e.g., the four linear portions of the first area A_1 may be arranged into a frame surrounding an entire perimeter of the second areas A_2 in a top view. In some embodiments, the second area A_2 may be a rectangular area at the center of the first surface 10_U, and the first area A_1 may be an area excluding the second area A_2 from the first surface 10_U.

In some embodiments, the first area A_1 may include the plurality of chip pads 20. The plurality of chip pads 20 may not be disposed in the second area A_2. In other words, the plurality of chip pads 20 may not be located in a central region of the first surface 10_U, e.g., the plurality of chip pads 20 may be only in the first area A_1 of the first surface 10_U.

In some embodiments, the substrate 10 may include one of a semiconductor material (e.g., silicon or germanium), an insulating material (e.g., glass or quartz), and a semiconductor or conductor covered by an insulating material. For example, the substrate 10 may be a wafer including silicon (Si). In another example, the substrate 10 may be a wafer including a semiconductor element, e.g., germanium (Ge), or a compound semiconductor, e.g., silicon carbide (SiC), gallium arsenide (GaAs), indium arsenide (InAs), or indium phosphide (InP). The substrate 10 may have a silicon on insulator (SOI) structure.

The plurality of chip pads 20 of the processor chip 100 may be arranged on the first surface 10_U. The plurality of chip pads 20 may be located on at least some of the four sides S_1, S_2, S_3, and S_4 of the first surface 10_U of the substrate 10. The plurality of chip pads 20 may be arranged along a side of the first surface 10_U of the substrate 10. That is, the plurality of chip pads 20 may be arranged in a line along a side of the first surface 10_U in at least some of the sides of the first surface 10_U of the substrate 10.

In other words, the plurality of chip pads 20 may be arranged along a side of the first surface 10_U in a direction parallel to the side of the first surface 10_U. In detail, the plurality of chip pads 20 may be arranged on at least some of the four sides of the first surface 10_U, and may be arranged in a line in a direction parallel to each adjacent side.

In some embodiments, the plurality of chip pads 20 may be arranged in a line along a side of the first surface 10_U in a direction parallel to the side of the first surface 10_U of the substrate 10. That is, the plurality of chip pads 20 may be arranged such that a maximum of two columns extend parallel to sides of the first surface 10_U. In other words, the plurality of chip pads 20 may be arranged in a line on two sides of the first surface 10_U that are parallel to each other.

In some embodiments, the plurality of chip pads 20 may be arranged in a line on each side of the first surface 10_U, and the plurality of chip pads 20 may be arranged in up to two columns between two sides facing each other. In other words, the plurality of chip pads 20 are not arranged in more than three columns between two sides facing each other.

In some embodiments, the plurality of chip pads 20 may include an input/output terminal performing a power pin function, an input/output terminal performing a ground pin function, or an input/output terminal performing a data pin function.

For example, the material of the plurality of chip pads 20 may include copper (Cu). In another example, the material of the plurality of chip pads 20 may include any suitable metal, e.g., nickel (Ni), gold (Au), silver (Ag), aluminum (Al), tungsten (W), titanium (Ti), tantalum (Ta), indium (In), molybdenum (Mo), manganese (Mn), cobalt (Co), tin (Sn), magnesium (Mg), rhenium (Re), beryllium (Be), gallium (Ga), or ruthenium (Ru), or an alloy thereof.

In some embodiments, the plurality of chip pads 20 may be respectively connected to a plurality of wires 21. In other words, the plurality of wires 21 may be respectively connected to the plurality of chip pads 20 that are different from one another. That is, the processor chip 100 may be electrically connected to the package substrate or the stacked structure by wire bonding.

In some embodiments, the plurality of wires 21 connected to the plurality of chip pads 20 arranged in different columns may pass over sides of the first surface 10_U that are different from each other. That is, the plurality of wires 21 connected to the plurality of chip pads 20 in different columns may be bent upward (e.g., over) sides of the first surface 10_U that are different from each other. In other words, a plurality of wires 21 passing over a same side of the first surface 10_U of the substrate 10 may be connected to a plurality of chip pads 20 arranged in a same column along the same side of the first surface 10_U of the substrate 10.

In the processor chip 100, the plurality of chip pads 20 are disposed along each side (e.g., along each edge) of the active surface, and thus, the plurality of chip pads 20 may not be disposed in the center of the active surface. That is, because the processor chip 100 has at most two columns of the plurality of chip pads 20 disposed in the same direction (e.g., along opposite edges), a structure may be stacked above the processor chip 100 (e.g., on the center of the active surface).

In some embodiments, the plurality of chip pads 20 may include a plurality of first chip pads 110 and a plurality of second chip pads 120. The plurality of first chip pads 110 may be arranged in a line along the first side S_1 of the first surface 10_U. The plurality of second chip pads 120 may be arranged in a line along the second side S_2 of the first surface 10_U.

In some embodiments, the first side S_1 may face the second side S_2. That is, the plurality of first chip pads 110 and the plurality of second chip pads 120 may be disposed on the first surface 10_U and face each other. For example, as illustrated in FIGS. 1 and 2, the first side S_1 and the second side S_2 may face each other. In another example, the first side S_1 and the second side S_2 may be perpendicular to each other.

In some embodiments, the first side S_1 and the second side S_2 may be long sides. In other words, among the four sides S_1, S_2, S_3, and S_4 of the first surface 10_U, the first side S_1 and the second side S_2 may be long sides. That is, among the first to fourth sides S_1 to S_4 of the first surface 10_U, the first side S_1 and the second side S_2 may be longer than each of the third side S_3 and the fourth side S_4.

In some embodiments, the number of first chip pads 110 may be the same as the number of second chip pads 120. That is, the number of chip pads 20 disposed on the first side S_1 of the first surface 10_U may be the same as the number of chip pads 20 disposed on the second side S_2.

In some embodiments, the plurality of first chip pads 110 may form (e.g., transmit) a first signal, and the plurality of second chip pads 120 may form (e.g., transmit) a second signal. The plurality of first chip pads 110 may be respectively connected to a plurality of first wires 111 (e.g., one-to-one correspondence), and the plurality of second chip pads 120 may be respectively connected to a plurality of second wires 121 (e.g., one-to-one correspondence). The first signal may be transmitted to the stacked structure through the plurality of first wires 111 and the second signal may be transmitted to the stacked structure through the plurality of second wires 121.

In some embodiments, the number of first chip pads 110 may be the same as the number of second chip pads 120. The arrangement order of the plurality of first chip pads 110 may be the same as the arrangement order of the plurality of second chip pads 120. In other words, the order of the output signals of the plurality of first chip pads 110 may be the same as the order of the output signals of the plurality of second chip pads 120.

In some embodiments, when the first side S_1 and the second side S_2 face each other, a first chip pad and a second chip pad facing each other based on the center line between the first side S_1 and the second side S_2 may output the same signal. In other words, the plurality of first chip pads 110 and the plurality of second chip pads 120 may be arranged in mirror symmetry with respect to the center line between the first side S_1 and the second side S_2.

In the processor chip 100, because the plurality of first chip pads 110 and the plurality of second chip pads 120 may be symmetrical to each other with respect to the center line of the first surface 10_U, errors in signal transmission may be reduced. In the process of wire-bonding the plurality of first chip pads 110 and the plurality of second chip pads 120 to substrate pads of the package substrate, changes in the order may be reduced because the order of the output signals of the plurality of first chip pads 110 is the same as the order of the output signals of the plurality of second chip pads 120.

In some embodiments, the plurality of chip pads 20 may include the plurality of first chip pads 110, the plurality of second chip pads 120, and a plurality of third chip pads 130. The plurality of first chip pads 110 may be arranged in a line along the first side S_1 of the first surface 10_U. The plurality of second chip pads 120 may be arranged in a line along the second side S_2 of the first surface 10_U. The plurality of third chip pads 130 may be arranged in a line along the third side S_3 of the first surface 10_U. In some embodiments, the first side S_1 and the second side S_2 may face each other, and the third side S_3 may be perpendicular to the first side S_1 and the second side S_2.

The plurality of first chip pads 110 and the plurality of second chip pads 120 may be connected to the stacked structure to transmit signals to the stacked structure. The plurality of third chip pads 130 may be connected to the package substrate to receive signals from the package substrate.

The plurality of first chip pads 110, the plurality of second chip pads 120, and the plurality of third chip pads 130 may be connected to the plurality of first wires 111, the plurality of second wires 121, and a plurality of third wires 131, respectively.

The plurality of first wires 111 may pass (e.g., extend only) over the first side S_1, the plurality of second wires 121 may pass (e.g., extend only) over the second side S_2, and the plurality of third wires 131 may pass (e.g., extend only) over the third side S_3. That is, each of the plurality of wires 21 may pass over a side adjacent to the plurality of chip pads 20 connected to the plurality of wires 21, e.g., so each of the plurality of wires 21 extends away from a center of the first surface 10_A without vertically overlapping or intersecting other wires 21. In some embodiments, the plurality of first wires 111 may pass over the first side S_1, the plurality of second wires 121 may pass over the second side S_2, and the plurality of third wires 131 may pass over the third side S_3.

The plurality of chip pads 20 of the processor chip 100 are arranged in at most two columns in a parallel direction, e.g., so all the chip pads 20 of the processor chip 100 may be aligned along two opposite edges of the processor chip 100 and spaced apart from a center of the processor chip 100. Thus, a phenomenon in which wires connected to a plurality of different chip pads 20 come into contact with each other may be prevented.

In addition, in the processor chip 100, the wires connected to the plurality of different chip pads 20 do not overlap each other in a vertical direction, e.g., so all the wires connected to the plurality of different chip pads 20 may vertically overlap only a periphery of the processor chip 100 (e.g., vertically overlappoing only a portion of the first surface 10_U between the chip pads 20 and the edge of the processor chip 100, without vertically overlapping any portions of the first surface 10_U between the chip pads 20 and the center of the first surface 10_U). Thus, a phenomenon in which the plurality of wires 21 come into contact with each other may be prevented.

FIG. 3 is a cross-sectional view schematically illustrating a semiconductor package 1000 according to an embodiment.

Referring to FIG. 3, the semiconductor package 1000 may include a package substrate 200, the processor chip 100, a first stacked structure 300, and a second stacked structure 400. In addition, the semiconductor package 1000 may further include an external connection member 500.

In some embodiments, the semiconductor package 1000 may be a multi-chip package (MCP) including different types of semiconductor chips. The semiconductor package 1000 may be a system in package (SIP) having an independent function by stacking or arranging a plurality of semiconductor chips in one package.

The package substrate 200 of the semiconductor package 1000 may be a substrate having an upper surface and a lower surface that face each other. For example, the package substrate 200 may include a printed circuit board (PCB), a flexible substrate, a tape substrate, and the like. The package substrate 200 may be a multilayer circuit board having vias and various circuits therein. The package substrate 200 may include internal wires serving as channels for electrical connection between the processor chip 100 and memory chips.

A plurality of substrate pads 210, 220, and 230 may be disposed on the upper surface of the package substrate 200. The substrate pads 210, 220, and 230 may be connected to the internal wires, respectively. The internal wires may extend from the upper surface or inside of the package substrate 200. For example, at least portions of the internal wires may be used as the substrate pads 210, 220, and 230 as landing pads.

The substrate pads 210, 220, and 230 of the package substrate 200 may include a first substrate pad 210, a second substrate pad 220, and a third substrate pad 230. The first substrate pad 210 may be a pad for electrically connecting the processor chip 100 to the first stacked structure 300. The second substrate pad 220 may be a pad for electrically connecting the processor chip 100 to the second stacked structure 400. The third substrate pad 230 may be a pad for electrically connecting the processor chip 100 to the package substrate 200.

A first insulating layer exposing the substrate pads 210, 220, and 230 may be formed on the upper surface of the package substrate 200. The first insulating layer may entirely cover an upper surface of the package substrate 200 except for the substrate pads 210, 220, and 230. For example, the first insulating layer may include a solder resist. Although only a few substrate pads are shown in the drawings, any suitable number and arrangement of the substrate pads may be used.

External connection pads 510 for providing electrical signals may be formed on the lower surface of the package substrate 200. The external connection pads 510 may be exposed by a second insulating layer. The second insulating layer may include, e.g., a silicon oxide layer, a silicon nitride layer, or a silicon oxynitride layer.

The external connection member 500 may be disposed on each of the external connection pads 510 of the package substrate 200 for electrical connection with external devices. For example, the external connection member 500 may be a solder ball.

The processor chip 100 of the semiconductor package 1000 may be mounted on the package substrate 200. The processor chip 100 may be attached to the upper surface of the package substrate 200 by using an adhesive member 101. For example, the adhesive member 101 may include an adhesive film, e.g., a direct adhesive film (DAF).

The processor chip 100 may include an integrated circuit. For example, the processor chip 100 may be a logic chip including a logic circuit. The logic chip may be a controller that controls memory chips. The processor chip 100 may be a processor chip, e.g., an application specific integrated circuit (ASIC) serving as a host, a central processing unit (CPU), a graphics processing unit (GPU), and a system on chip (SoC).

The processor chip 100 may include a plurality of chip pads 20. The processor chip 100 may be divided into a first area and a second area, the first area may include four sides of the upper surface of the processor chip 100, and the second area may be surrounded by the first area. The plurality of chip pads 20 may be located in the first area and may be arranged in a line in a direction parallel to each side in at least some of the four sides of the upper surface of the processor chip 100. In some embodiments, the processor chip 100 of the semiconductor package 1000 may include the processor chip 100 shown in FIGS. 1 and 2.

In some embodiments, the processor chip 100 may include the plurality of first chip pads 110 arranged in a line on a first side. The processor chip 100 may include the plurality of second chip pads 120 arranged in a line on a second side. The processor chip 100 may include the plurality of third chip pads 130 arranged in a line on a third side.

In some embodiments, the processor chip 100 may include the plurality of first wires 111, the plurality of second wires 121, and the plurality of third wires 131. The plurality of first wires 111 may connect the first substrate pad 210 to the plurality of first chip pads 110. The plurality of second wires 121 may connect the second substrate pad 220 to the plurality of second chip pads 120. The plurality of third wires 131 may connect the third substrate pad 230 to the plurality of third chip pads 130. That is, the processor chip 100 may be electrically connected to the package substrate 200 through the plurality of first wires 111 to the plurality of third wires 131.

The first stacked structure 300 of the semiconductor package 1000 may be located on the package substrate 200. In some embodiments, the first stacked structure 300 may be mounted on the upper surface of the package substrate 200. In some embodiments, the first stacked structure 300 may be mounted on the upper surface of the processor chip 100.

The first stacked structure 300 may include a plurality of first memory chips 300a, 300b, 300c, and 300d sequentially stacked. For example, each of the first memory chips 300a, 300b, 300c, and 300d may include a dynamic random access memory (DRAM) or a non-volatile memory device, e.g., a NAND flash memory.

The plurality of first memory chips 300a, 300b, 300c, and 300d of the first stacked structure 300 may be sequentially stacked using adhesive members 301a, 301b, 301c, and 301d. The plurality of first memory chips 300a, 300b, 300c, and 300d may be offset-stacked. That is, the plurality of first memory chips 300a, 300b, 300c, and 300dmay be stacked in a cascade structure. In other words, the plurality of first memory chips 300a, 300b, 300c, and 300d may be stacked in a stepwise manner.

In some embodiments, the semiconductor package 1000 may further include a plurality of third wires 211 connecting the plurality of first memory chips 300a, 300b, 300c, and 300d of the first stacked structure 300 to at least some of the plurality of first substrate pads 210. In other words, the first stacked structure 300 may be electrically connected to the package substrate 200 through wire bonding. In detail, the processor chip 100 and the first stacked structure 300 may be electrically connected to each other through the first substrate pad 210.

The second stacked structure 400 of the semiconductor package 1000 may be located on the package substrate 200. In some embodiments, the second stacked structure 400 may be mounted on the upper surface of the package substrate 200. In some embodiments, the second stacked structure 400 may be mounted on the upper surface of the processor chip 100.

The second stacked structure 400 may include a plurality of second memory chips 400a, 400b, 400c, and 400d sequentially stacked. For example, each of the second memory chips 400a, 400b, 400c, and 400d may include a DRAM or a non-volatile memory device, e.g., a NAND flash memory.

The plurality of second memory chips 400a, 400b, 400c, and 400d of the second stacked structure 400 may be sequentially stacked using adhesive members 401a, 401b, 401c, and 401d. The plurality of second memory chips 400a, 400b, 400c, and 400d may be offset-stacked. That is, the plurality of second memory chips 400a, 400b, 400c, and 400d may be stacked in a cascade structure. In other words, the plurality of second memory chips 400a, 400b, 400c, and 400d may be stacked in a stepwise manner.

In some embodiments, the semiconductor package 1000 may further include a plurality of fourth wires 221 connecting the plurality of second memory chips 400a, 400b, 400c, and 400d of the second stacked structure 400 to at least some of the plurality of second substrate pads 220. In other words, the second stacked structure 400 may be electrically connected to the package substrate 200 through wire bonding. In detail, the processor chip 100 and the second stacked structure 400 may be electrically connected to each other through the second substrate pad 220.

In some embodiments, the second stacked structure 400 may be spaced apart from the first stacked structure 300, e.g., along a horizontal direction parallel to an upper surface of the package substrate 200, with the processor chip 100 therebetween. That is, the first stacked structure 300 and the second stacked structure 400 may be mounted at both, e.g., opposite, sides of the processor chip 100 on the upper surface of the package substrate 200. In some embodiments, the plurality of first chip pads 110 of the processor chip 100 may be adjacent to the first stacked structure 300, and the plurality of second chip pads 120 may be adjacent to the second stacked structure 400. The plurality of first chip pads 110 may be electrically connected to the first stacked structure 300 through the first substrate pad 210, and the plurality of second chip pads 120 may be electrically connected to the second stacked structure 400 through the second substrate pad 220.

In the semiconductor package 1000 according to the present embodiment, the processor chip 100 may be electrically connected to the first stacked structure 300 or the second stacked structure 400 through the package substrate 200. Because the processor chip 100 is between the first stacked structure 300 and the second stacked structure 400, the overall thickness of the semiconductor package 1000 may be maintained the same and the thicknesses of the first memory chips 300a, 300b, 300c, and 300d and the second memory chips 400a, 400b, 400c, and 400d may be increased. As the thicknesses of the first memory chips 300a, 300b, 300c, and 300d and the second memory chips 400a, 400b, 400c, and 400 increase, the structural stability of the semiconductor package 1000 may increase.

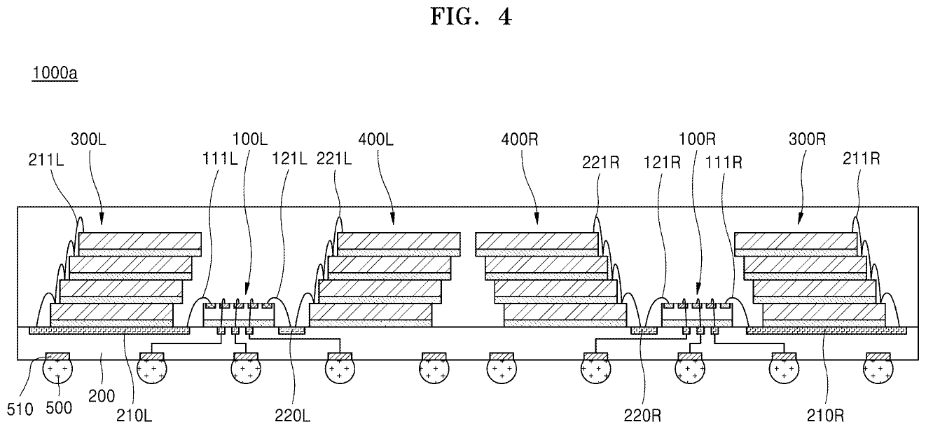

FIG. 4 is a cross-sectional view schematically illustrating a semiconductor package 1000a according to an embodiment.

Referring to FIG. 4, the semiconductor package 1000a may include the package substrate 200, a plurality of processor chips 100L and 100R, a plurality of first stacked structures 300L and 300R, and a plurality of second stacked structures 400L and 400R. Hereinafter, descriptions of the semiconductor package 1000a that are redundant relative to those of the semiconductor package 1000 of FIG. 3 are omitted and the differences therebetween are mainly described.

The plurality of first stacked structures 300L and 300R may be offset-stacked in opposite directions. That is, one first stacked structure 300L may be offset-stacked such that one side thereof protrudes, and the other first stacked structure 300R may be offset-stacked such that the other side thereof protrudes. The one first stacked structure 300L and the other first stacked structure 300R may be spaced from each other and located on the package substrate 200.

In some embodiments, the one first stacked structure 300L and the other first stacked structure 300R may be located such that their protruding portions face each other. That is, as the distance from the package substrate 200 increases, a separation distance between the plurality of first stacked structures 300L and 300R may decrease.

The plurality of second stacked structures 400L and 400R may be offset-stacked in opposite directions. That is, one second stacked structure 400L may be offset-stacked such that one side thereof protrudes, and the other second stacked structure 400R may be offset-stacked such that the other side thereof protrudes. The one second stacked structure 400L and the other second stacked structure 400R may be spaced apart from each other and located on the package substrate 200.

In some embodiments, the one second stacked structure 400L and the other second stacked structure 400R may be located such that their protruding portions face each other. That is, as the distance from the package substrate 200 increases, a separation distance between the plurality of second stacked structures 400L and 400R may decrease.

The first stacked structure 300L and the second stacked structure 400L may be respectively located on both sides of the processor chip 100L, and the first stacked structure 300R and the second stacked structure 400R may be respectively located on both sides of the processor chip 100R. Specifically, each of the plurality of processor chips 100L and 100R may be between a first stacked structure and a second stacked structure that are offset-stacked in the same direction.

In some embodiments, the first stacked structure 300L and the processor chip 100L, which are located in a first area of the package substrate 200, may be electrically connected to each other through a plurality of first wires 111L, a plurality of first substrate pads 210L, and a plurality of third wires 211L, which are located in the first area. The first stacked structure 300R and the processor chip 100R, which are located in a second area of the package substrate 200, may be electrically connected to each other through a plurality of first wires 111R, a plurality of first substrate pads 210R, and a plurality of third wires 211R, which are located in the second area.

In some embodiments, the second stacked structure 400L and the processor chip 100L, which are located in the first area of the package substrate 200, may be electrically connected to each other through a plurality of second wires 121L, a plurality of second substrate pads 220L, and a plurality of fourth wires 221L, which are located in the first area. The second stacked structure 400R and the processor chip 100R, which are located in the second area of the package substrate 200, may be electrically connected to each other through a plurality of second wires 121R, a plurality of second substrate pads 220R, and a plurality of fourth wires 221R, which are located in the second area.

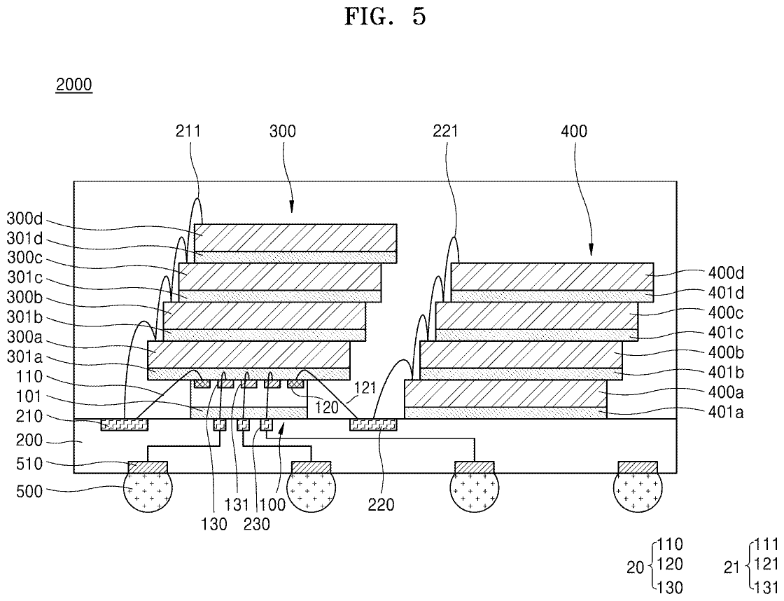

FIG. 5 is a cross-sectional view schematically illustrating a semiconductor package 2000 according to an embodiment.

Referring to FIG. 5, the semiconductor package 2000 may include the package substrate 200, the processor chip 100, the first stacked structure 300, and the second stacked structure 400. Hereinafter, descriptions of the semiconductor package 2000 that are redundant relative to those of the semiconductor package 1000 of FIG. 3 are omitted and the differences therebetween are mainly described.

As illustrated I FIG. 5, the first stacked structure 300 may be mounted on the upper surface of the processor chip 100. That is, the processor chip 100 may be located below the first stacked structure 300, e.g., the processor chip 100 may be between a bottom of the first stacked structure 300 and a top of the package substrate 200. In other words, the first stacked structure 300 may be attached to an upper portion of a first surface of the processor chip 100 by using an adhesive member 301a.

The second stacked structure 400 may be spaced apart from the first stacked structure 300 and located on (e.g., directly on) the package substrate 200. That is, the second stacked structure 400 may be attached onto the package substrate 200 by using an adhesive member 401 and may be spaced apart from the first stacked structure 300 and the processor chip 100. In some embodiments, the first stacked structure 300 and the second stacked structure 400 may be offset-stacked in the same direction.

In the semiconductor package 2000, a plurality of chip pads 20 of the processor chip 100 may be arranged in a line along four sides of the first surface, and thus, there may be no overlapping in a vertical direction between the plurality of wires 21 used for wire bonding. Therefore, even when the first stacked structure 300 is attached to the upper surface of the processor chip 100, contact between the plurality of wires 21 may be suppressed (e.g., prevented) or substantially minimized.

In the semiconductor package 2000, as contact between the plurality of wires 21 is suppressed by the plurality of chip pads 20 arranged in a line, a structure may be stacked on top of the processor chip 100. When the first stacked structure 300 is attached to the top of the processor chip 100, the size of the semiconductor package 2000 may be reduced.

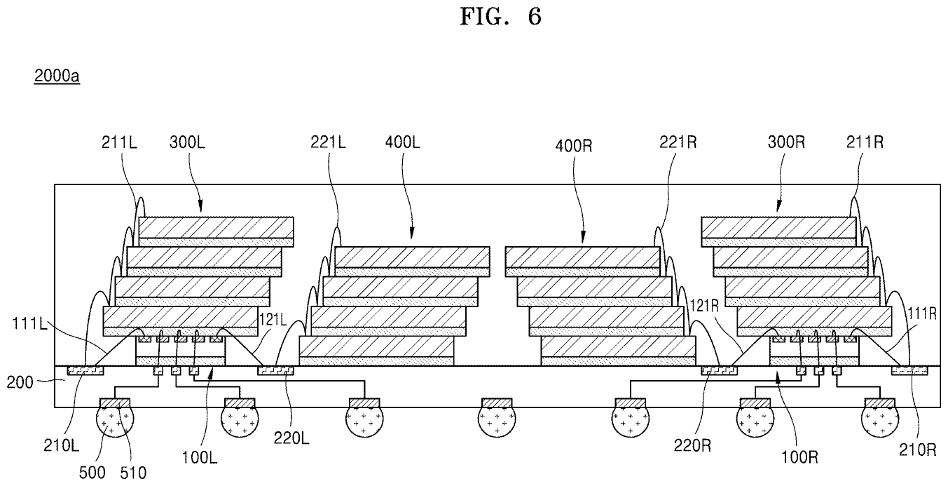

FIG. 6 is a cross-sectional view schematically illustrating a semiconductor package 2000a according to an embodiment.

Referring to FIG. 6, the semiconductor package 2000a may include the package substrate 200, the plurality of processor chips 100L and 100R, the plurality of first stacked structures 300L and 300R, and the plurality of second stacked structures 400L and 400R. Hereinafter, descriptions of the semiconductor package 2000a that are redundant relative to those of the semiconductor package 2000 of FIG. 5 are omitted and the differences therebetween are mainly described.

As illustrated in FIG. 6, the plurality of first stacked structures 300L and 300R may be offset-stacked in opposite directions. That is, one first stacked structure 300L may be offset-stacked such that one side thereof protrudes, and the other first stacked structure 300R may be offset-stacked such that the other side thereof protrudes. The one first stacked structure 300L and the other first stacked structure 300R may be spaced apart from each other and located on the package substrate 200.

In some embodiments, the one first stacked structure 300L and the other first stacked structure 300R may be located such that their protruding portions face each other. That is, as the distance from the package substrate 200 increases, a separation distance between the plurality of first stacked structures 300L and 300R may decrease.

The plurality of second stacked structures 400L and 400R may be offset-stacked in opposite directions. That is, one second stacked structure 400L may be offset-stacked such that one side thereof protrudes, and the other second stacked structure 400R may be offset-stacked such that the other side thereof protrudes. The one second stacked structure 400L and the other second stacked structure 400R may be spaced apart from each other and located on the package substrate 200.

In some embodiments, the one second stacked structure 400L and the other second stacked structure 400R may be located such that their protruding portions face each other. That is, as the distance from the package substrate 200 increases, a separation distance between the plurality of second stacked structures 400L and 400R may decrease.

The plurality of processor chips 100L and 100R may be located below different first stacked structures 300L and 300R, respectively. That is, the plurality of first stacked structures 300L and 300R may be disposed on the upper surfaces of different processor chips 100L and 100R, respectively.

In some embodiments, the semiconductor package 2000a may be divided into a first area and a second area. The first area may include the first stacked structure 300L, the second stacked structure 400L, and the processor chip 100L, and the second area may include the first stacked structure 300R, the second stacked structure 400R, and the processor chip 100R. A method of electrically connecting the first stacked structure 300L, the second stacked structure 400L, and the processor chip 100L in the first area, and electrically connecting the first stacked structure 300R, the second stacked structure 400R, and the processor chip 100R in the second area may be the wire bonding method described with reference to FIG. 4.

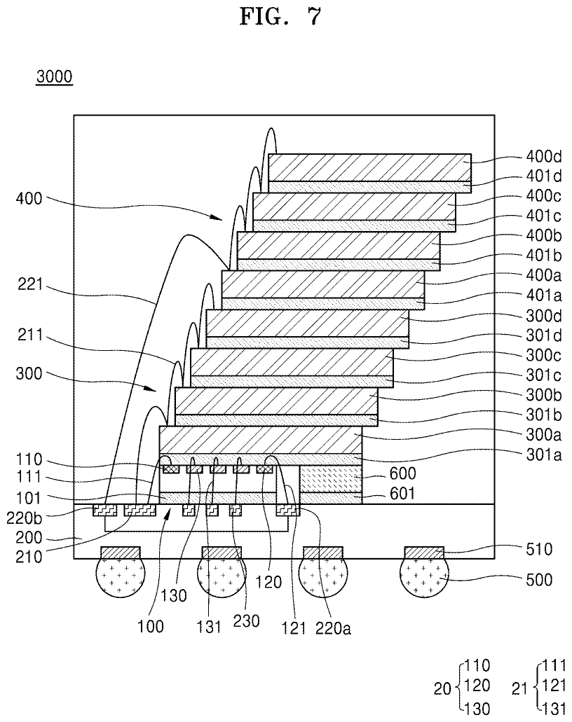

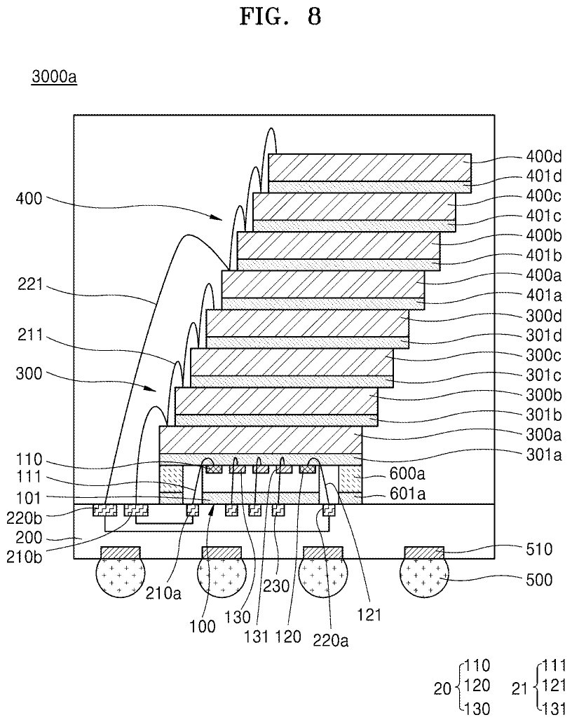

FIG. 7 is a cross-sectional view schematically illustrating a semiconductor package 3000 according to an embodiment. FIG. 8 is a cross-sectional view schematically illustrating a semiconductor package 3000a according to an embodiment.

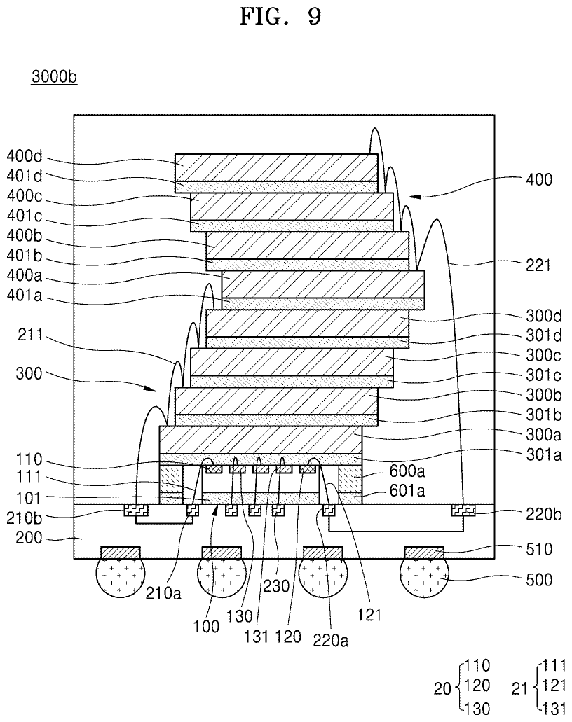

FIG. 9 is a cross-sectional view schematically illustrating a semiconductor package 3000b according to an embodiment.

Referring to FIGS. 7 to 9, each of the semiconductor packages 3000, 3000a, and 3000b may include the package substrate 200, the processor chip 100, the first stacked structure 300, the second stacked structure 400, and a support structure 600 or 600a. Hereinafter, descriptions of the semiconductor packages 3000, 3000a, and 3000b that are redundant relative to those of the semiconductor package 1000 of FIG. 3 are omitted and the differences therebetween are mainly described.

As illustrated in FIG. 7, the support structure 600 of the semiconductor package 3000 may be spaced apart from the processor chip 100 on the package substrate 200. The support structure 600 may be attached to the upper surface of the package substrate 200 by using an adhesive member 601. The support structure 600 may include a dummy substrate or a dummy chip.

The thickness of the support structure 600 may be determined considering the thickness of the processor chip 100. The height of the processor chip 100 on the package substrate 200 may be the same as that of the support structure 600. Accordingly, the upper surface of the processor chip 100 and the upper surface of the support structure 600 may be on the same plane, e.g., the upper surfaces of the processor chip 100 and the support structure 600 may be coplanar.

For example, as illustrated in FIG. 7, the support structure 600 may be located on one side of the processor chip 100. In another example, as illustrated in FIG. 8, a support structure 600a may include a hole accommodating the processor chip 100, and the support structure 600a may surround the processor chip 100.

In some embodiments, a first substrate pad 210a in contact with a plurality of first wires 111 connected to a plurality of first chip pads 110 may be spaced apart from a first substrate pad 210b in contact with a plurality of third wires 211 connected to the first stacked structure 300, but the first substrate pad 210a and the first substrate pad 210b may be electrically connected to each other. That is, the plurality of first substrate pads 210a and 210b that are spaced apart from each other may be electrically connected to each other through internal wires.

In some embodiments, a second substrate pad 220a in contact with a plurality of second wires 121 connected to a plurality of second chip pads 120 may be spaced apart from a second substrate pad 220b in contact with a plurality of fourth wires 221 connected to the second stacked structure 400, but the second substrate pad 220a and the second substrate pad 220b may be electrically connected to each other. That is, the plurality of second substrate pads 220a and 220b that are spaced apart from each other may be electrically connected to each other through internal wires.

Referring back to FIG. 7, the second substrate pad 220a connected to the plurality of second chip pads 120 may be between the processor chip 100 and the support structure 600. The second substrate pad 220b connected to the second stacked structure 400 may be spaced apart from the support structure 600 with the processor chip 100 therebetween. The second substrate pad 220a connected to the processor chip 100 and the second substrate pad 220b connected to the second stacked structure 400 may be electrically connected to each other through internal wires.

Referring to FIGS. 8 and 9, a first substrate pad 210a connected to a plurality of first chip pads 110 and a second substrate pad 220a connected to a plurality of second chip pads 120 may be between the processor chip 100 and the support structure 600a. A first substrate pad 210b connected to the first stacked structure 300 and a second substrate pad 220b connected to the second stacked structure 400 may be located in an area in which the support structure 600a and the package substrate 200 do not overlap each other. The first substrate pad 210a connected to the processor chip 100 and the first substrate pad 210b connected to the first stacked structure 300 may be electrically connected to each other through internal wires. The second substrate pad 220a connected to the processor chip 100 and the second substrate pad 220b connected to the second stacked structure 400 may be electrically connected to each other through internal wires.

The first stacked structure 300 may be mounted on (e.g., directly on) the upper surfaces of the processor chip 100 and the support structure 600. The second stacked structure 400 may be offset-stacked on the upper surface of the first stacked structure 300. That is, the first stacked structure 300 and the second stacked structure 400 may be offset-stacked on top of the processor chip 100 and the support structure 600.

Referring to FIGS. 7 and 8, the first stacked structure 300 and the second stacked structure 400 may be offset-stacked to protrude in the same direction. That is, a first stacked structure may be offset-stacked such that one side of each of memory chips protrudes, and in a second stacked structure, memory chips may be offset-stacked such that a side parallel to the protruding side of each of the memory chips of the first stacked structure protrudes.

Referring to FIG. 9, the first stacked structure 300 and the second stacked structure 400 may be offset-stacked to protrude in opposite directions. That is, a first stacked structure may be offset-stacked such that one side of each of memory chips thereof protrudes, and a second stacked structure may be offset-stacked such that the other side of each of memory chips thereof protrudes.

In the semiconductor packages 3000, 3000a, and 3000b according to the present embodiments, a plurality of chip pads 20 of the processor chip 100 may be arranged in a line along four sides of a first surface, and thus, there may be no overlapping in a vertical direction between a plurality of wires 21 used for wire bonding. Therefore, even when the first stacked structure 300 is attached to the upper surface of the processor chip 100, contact between the plurality of wires 21 may be suppressed.

The semiconductor packages 3000, 3000a, and 3000b may further include the support structure 600 or 600a, and thus, the second stacked structure 400 may be stably mounted on the processor chip 100. In addition, the sizes of the semiconductor packages 3000, 3000a, and 3000b may be reduced by mounting the first stacked structure 300 and the second stacked structure 400 on the processor chip 100.

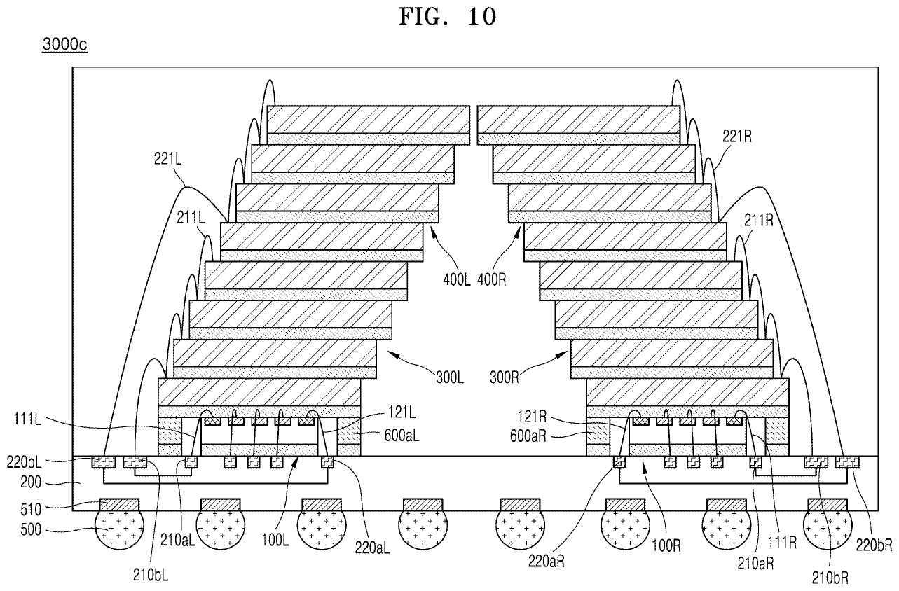

FIG. 10 is a schematic cross-sectional view of a semiconductor package 3000caccording to an embodiment.

Referring to FIG. 10, the semiconductor package 3000c may include the package substrate 200, the plurality of processor chips 100L and 100R, the plurality of first stacked structures 300L and 300R, the plurality of second stacked structures 400L and 400R, and a plurality of support structures 600aL and 600aR. Hereinafter, descriptions of the semiconductor package 3000c that are redundant relative to those of the semiconductor package 3000a of FIG. 8 are omitted and the differences therebetween are mainly described.

As illustrated in FIG. 10, the plurality of first stacked structures 300L and 300R may be offset-stacked in opposite directions. That is, one first stacked structure 300L may be offset-stacked such that one side thereof protrudes, and the other first stacked structure 300R may be offset-stacked such that the other side thereof protrudes. The one first stacked structure 300L and the other first stacked structure 300R may be spaced apart from each other and located on the package substrate 200.

In some embodiments, the one first stacked structure 300L and the other first stacked structure 300R may be located such that their protruding portions face each other. That is, as the distance from the package substrate 200 increases, a separation distance between the plurality of first stacked structures 300L and 300R may decrease.

The plurality of second stacked structures 400L and 400R may be offset-stacked in opposite directions. That is, one second stacked structure 400L may be offset-stacked such that one side thereof protrudes, and the other second stacked structure 400R may be offset-stacked such that the other side thereof protrudes. The one second stacked structure 400L and the other second stacked structure 400R may be apart from each other and located on the package substrate 200.

In some embodiments, the one second stacked structure 400L and the other second stacked structure 400R may be located such that their protruding portions face each other. That is, as the distance from the package substrate 200 increases, a separation distance between the plurality of second stacked structures 400L and 400R may decrease.

The first stacked structure 300L and the second stacked structure 400L may be mounted on the upper surface of the processor chip 100L, and the first stacked structure 300R and the second stacked structure 400R may be mounted on the upper surface of the processor chip 100R. Referring to FIG. 10, the first stacked structure 300L and the second stacked structure 400L, which are offset-stacked in the same direction, may be mounted on the upper surface of the same processor chip 100L.

In some embodiments, first substrate pads 210aL, 210bL, 210aR, and 210bR and second substrate pads 220aL, 220bL, 220aR, and 220bR of the package substrate 200 may include the first substrate pads 210a and 210b and the second substrate pads 220a and 220b, respectively, described with reference to FIGS. 8 and 9.

In some embodiments, the semiconductor package 3000c may be divided into a first area and a second area. The first area may include the first stacked structure 300L, the second stacked structure 400L, and the processor chip 100L, and the second area may include the first stacked structure 300R, the second stacked structure 400R, and the processor chip 100R. A method of electrically connecting the first stacked structure 300L, the second stacked structure 400L, and the processor chip 100L in the first area and electrically connecting the first stacked structure 300R, the second stacked structure 400R, and the processor chip 100R in the second area may be the wire bonding method described with reference to FIG. 4.

By way of summation and review, when semiconductor chips are arranged in parallel, an overhang portion may sag due to the size difference between chips of the same type or a heterogeneous type, and when the number of channels of chips arranged in parallel is symmetrical, a package thickness reduction restriction may occur. Accordingly, a package structure in which a large number of chips are embedded while limiting the package thickness to be small is required.

Therefore, embodiments provide a processor chip on which a stacked structure may be stacked, and a semiconductor package including the processor chip. Embodiments also provide a processor chip having a symmetrical chip pad and a semiconductor package including the processor chip.

That is, in a processor chip (i.e., a buffer chip) according to embodiments, chip pads may be arranged only at the edges, thereby preventing or substantially minimizing overlap between wires and a short-circuit therebetween. As such, even if a memory chip is mounted on (e.g., above) the processor chip, contact between wires connected to the processor chip may be prevented or substantially minimized.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A processor chip for a semiconductor package, the processor chip comprising:
a substrate having a first surface and a second surface opposite to each other, the first surface including a first area and a second area, the first area including four sides of the first surface, the second area including a center of the first surface, and the second surface of the substrate being mounted on a package substrate; and
chip pads on the first area of the first surface of the substrate, the chip pads being electrically connected to the package substrate, and the chip pads being arranged in a line along at least a portion of the four sides of the first surface.

2. The processor chip as claimed in claim 1, further comprising wires connected to the chip pads that are different from one another.

3. The processor chip as claimed in claim 2, wherein the chip pads are not arranged on the second area.

4. The processor chip as claimed in claim 2, wherein:
the chip pads are arranged in a line along at least two of the four sides of the first surface, and
the wires connected to respective ones of the chip pads extend in a direction oriented from the respective ones of the chip pads toward and over the at least two of the four sides of the first surface, respectively.

5. The processor chip as claimed in claim 1, wherein a thickness of the substrate is about 40 μm to about 60 μm.

6. The processor chip as claimed in claim 1, wherein each of the chip pads includes an input/output terminal.

7. The processor chip as claimed in claim 1, wherein the chip pads include:
first chip pads along a first side of the first surface; and
second chip pads along a second side facing the first side.

8. The processor chip as claimed in claim 7, wherein:
a number of the first chip pads is the same as a number of the second chip pads, and
an order of output signals of the first chip pads is the same as an order of output signals of the second chip pads.

9. The processor chip as claimed in claim 7, wherein, among the four sides of the first surface, the first side and the second side are longer than other sides.

10. A semiconductor package, comprising:
a package substrate including substrate pads;
a processor chip on the package substrate, the processor chip including chip pads on an upper surface of the processor chip;
a first stacked structure on the package substrate, the first stacked structure including offset-stacked first memory chips; and
a second stacked structure on the package substrate, the second stacked structure including offset-stacked second memory chips,
wherein the processor chip includes a first area and a second area, the first area having four sides of the upper surface of the processor chip that surround the second area, and the chip pads being on the first area and being arranged in a line on at least two of the four sides of the upper surface in a direction parallel to the at least two of the four sides of the upper surface.

11. The semiconductor package as claimed in claim 10, wherein the chip pads include:
first chip pads arranged on a first side of the upper surface of the processor chip in a line along the first side; and
second chip pads arranged on a second side of the upper surface of the processor chip in a line along the second side.

12. The semiconductor package as claimed in claim 11, wherein the substrate pads include first substrate pads and second substrate pads,
the semiconductor package further comprising:
first wires electrically connecting at least some of the first substrate pads to the first chip pads; and
second wires electrically connecting at least some of the second substrate pads to the second chip pads.

13. The semiconductor package as claimed in claim 12, further comprising:
third wires connecting at least some of the first substrate pads to the first stacked structure; and
fourth wires connecting at least some of the second substrate pads to the second stacked structure.

14. The semiconductor package as claimed in claim 13, wherein:
among the first substrate pads, one first substrate pad connected to one of the first wires and another first substrate pad connected to one of the third wires are connected to each other by first internal wires, and
among the second substrate pads, one second substrate pad connected to one of the second wires and another second substrate pad connected to one of the fourth wires are connected to each other by second internal wires.

15. The semiconductor package as claimed in claim 10, wherein the processor chip is below the first stacked structure, and the second stacked structure is spaced apart from the processor chip and mounted on the package substrate.

16. The semiconductor package as claimed in claim 10, further comprising a support structure on the package substrate, the support structure and the processor chip being below the first stacked structure.

17. The semiconductor package as claimed in claim 16, wherein the second stacked structure is offset-stacked on the first stacked structure.

18. The semiconductor package as claimed in claim 10, wherein the second stacked structure is spaced apart from the first stacked structure with the processor chip therebetween and is mounted on the package substrate.

19. The semiconductor package as claimed in claim 10, wherein the processor chip is attached to the package substrate by an adhesive member.

20. A semiconductor package, comprising:
a package substrate including first substrate pads and second substrate pads;
a processor chip on the package substrate, the processor chip including first chip pads and second chip pads on an upper surface of the processor chip;
a first stacked structure on the package substrate, the first stacked structure including offset-stacked first memory chips; and
a second stacked structure on the package substrate, the second stacked structure including offset-stacked second memory chips,
wherein:
the processor chip includes a first area and a second area, the first area having four sides of the upper surface of the processor chip and surrounding the second area,
the first chip pads and the second chip pads are on the first area and are arranged in a line along at least two of the four sides of the upper surface in a direction parallel to the at least two of the four sides of the upper surface,
the processor chip and the first stacked structure are wire-bonded to each other through the first substrate pads, and
the processor chip and the second stacked structure are wire-bonded to each other through the second substrate pads.
